(19) United States
(12) Patent Application Publication
(10) Pub. No.: US 2016/0109902 A1
(43) Pub. Date: Apr. 21, 2016

(54) ELECTRONIC DEVICE ENCLOSURE

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: LIANG-CHIN WANG, New Taipei (TW); YU-MING XIAO, Wuhan (CN); LIN DING, Wuhan (CN); XIAO-FANG HE, Wuhan (CN)

(21) Appl. No.: 14/527,164

(22) Filed: Oct. 29, 2014

(30) Foreign Application Priority Data
Oct. 15, 2014 (CN) 201410543609.3

(51) Int. Cl. G06F 1/16; H05K 5/02; H05K 5/00

(52) U.S. Cl. CPC G06F 1/16; H05K 5/0004; H05K 5/02

(57) ABSTRACT

Electronic device enclosure includes a front frame and a front panel. The front frame includes a front frame body. A front flange extends from the front frame body to define a front panel sliding slot, and the front panel is made of a non-metal material and is slidably received in the front panel sliding slot, thereby the front panel is coupled to the front frame.

### FIELD

The subject matter herein generally relates to an electronic device enclosure. The electronic device enclosure can include space to receive various components, for example components for a personal computer.

### BACKGROUND

An electronic device enclosure such as a personal computer chassis often includes a main body and a cover attached to the main body. The main body includes a bottom plate, two side plates, a top plate cooperatively defining a receiving area for receiving electronic components therein. The electronic components can include a motherboard, hard disks, a plurality of expansion cards, power supply. The computer chassis can be metal.

### BRIEF DESCRIPTION OF THE DRAWINGS

Implementations of the present technology will now be described, by way of example only, with reference to the attached figures.

FIG. 1 is an exploded, isometric view of an embodiment of an electronic device enclosure.

FIG. 2 is an exploded, isometric view of a front frame, two side frames and a bracket of the electronic device enclosure of FIG. 1.

FIG. 3 is an assembled view of the electronic device enclosure of FIG. 1, but without a top panel.

FIG. 4 is an assembled view of the electronic device enclosure of FIG. 1, but without the bracket.

FIG. 5 is an assembled view of the electronic device enclosure of FIG. 1.

FIG. 6 is similar to FIG. 5, but viewed from a different angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to an electronic device enclosure comprising a front frame and a front panel. The front frame includes a front frame body. A front flange extends from the front frame body to define a front panel sliding slot, and the front panel is made of nonmetal material and is slidable received in the front panel sliding slot, thereby the front panel is coupled to the front frame.

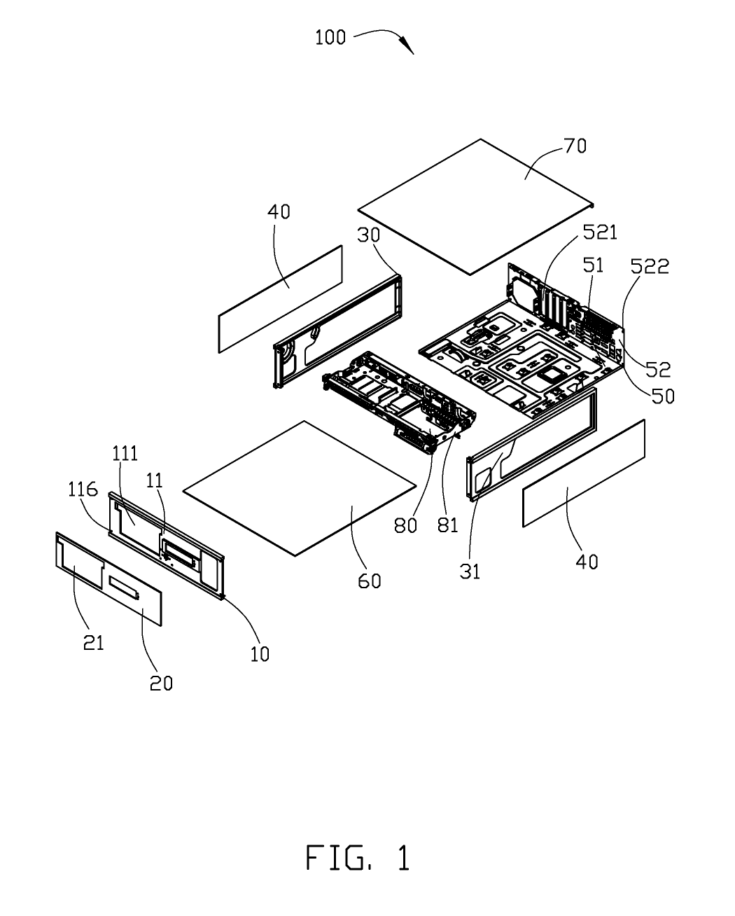

FIG. 1 illustrates an embodiment of an electronic device enclosure 100. The electronic device enclosure 100 comprises a front frame 10, a front panel 20, two side frames 30, two side panels 40, a bottom frame 50, a bottom panel 60, a top panel 70, and a bracket 80. The front panel 20, the side panels 40, the bottom panel 60, and the top panel 70 are made of non-metal material, such as paper, wood, bamboo, plastic, etc. The non-metal material can have a less weigh than metal.

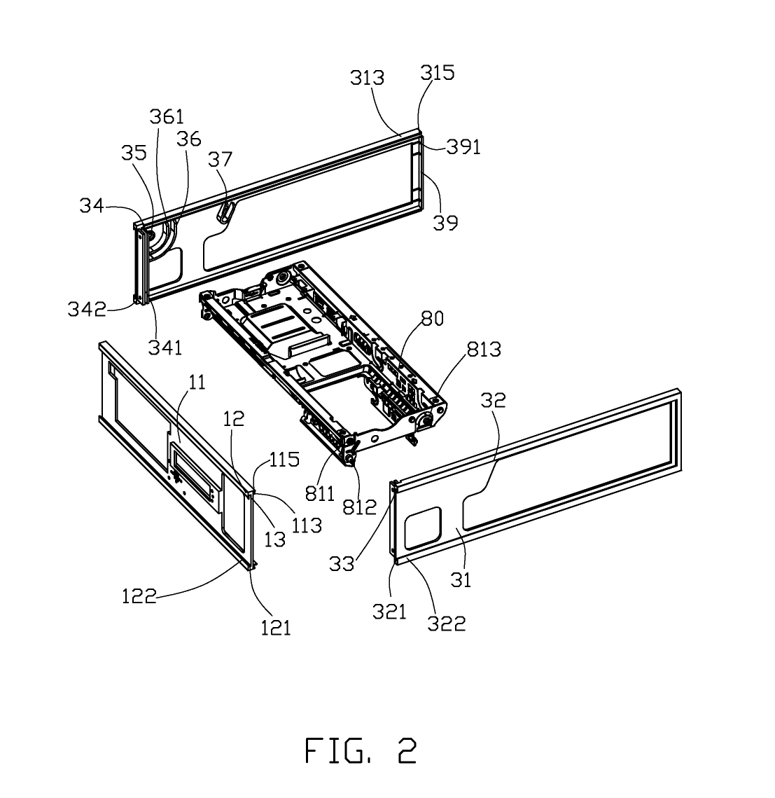

FIG. 2 illustrates an embodiment of the electronic device enclosure 100. The front frame 10 comprises a front frame body 11 with a plurality openings 111 defined thereon. Two front flanges 12 extends from opposite edges of the front frame body 11, and each front flange 12 comprises a coupling portion 121 substantially perpendicular to the front frame body 121 and a bending portion 122 coupled to the coupling portion 121. The bending portion 122 is substantially perpendicular to the coupling portion 121 and parallel to the front frame body 11, so that a front panel sliding slot 13 can be defined between the bending portion 122 and the front frame body 11. A pair of limiting ribs 113 are located on opposite edges of the front frame body 11. Each limiting rib 113 is substantially perpendicular to the front frame body 11, so that a receiving slot 115 is defined between the pair of limiting ribs 113. A pair of securing holes 116 is defined on opposite sides of the front frame body 11.

The front panel 20 can be slid into the two front panel sliding slots 13 to secure to the front frame body 11. A plurality of holes 21, corresponding to the plurality of openings 111, is defined in the front panel 20.

Each side frame 30 comprises a side frame body 31. The side frame body 31 can be hollow. A pair of side flanges 32 extend from opposite edges of the side frame body 31, and each side flange 32 comprises a connecting portion 321 substantially perpendicular to the side frame body 31 and an extending portion 322 coupled to the connecting portion 321. The extending portion 322 is substantially perpendicular to the connecting portion 321 and parallel to the side frame body 31, so that a side panel sliding slot 33 can be defined between the extending portion 322 and the side frame body 31. A pair of limiting pieces 313 are located on opposite edges of the side frame body 31. Each limiting piece 313 is substantially perpendicular to the side frame body 31, so that an accommodating slot 315 is defined between the pair of limiting ribs 313.

Two positioning pieces 34, two blocking pieces 36, and a supporting portion 37 are located on a front of each side frame body 31. The two positioning pieces 34 are substantially perpendicular to the side frame body 31 and parallel to each other, so that a clipping portion 341 is defined between the two positioning pieces 34. Two mounting holes 342, corresponding to the two securing holes 116, are defined in each positioning piece 34. Each blocking piece 36 is substantially arcuate and aligned with each other, so that an arcuate sliding slot 361 is defined between the two blocking piece 36. A rotating hole 35 is defined in the side frame body 31, and a center of a circle defined by the sliding slot 361 is coincided with the rotating hole 35. A fixing piece 39, with fixing holes 391, is located on a rear of the side frame body 31.

The side panel 40 can be slid into the two side panel sliding slots 33 to secure to the side frame body 31.

The bottom frame 50 comprises a bottom portion 51 and a rear portion 52 substantially perpendicular to the bottom portion 51. The bottom portion 51 is used to support electronic components, such as motherboards thereon. A plurality of expansion slots 521 and through holes 522 is defined in the rear portion 52. The plurality of expansion slots 521 is used to engage with expansion cards (not shown), and the plurality of through holes 522 corresponds to the fixing holes 391.

The bottom panel 60 can be coupled to a bottom surface of the bottom portion 51.

The bracket 80 comprises two side portions 81. Each side portion 81 comprises a rotating post 811, a sliding post 812, and a protruding post 813.

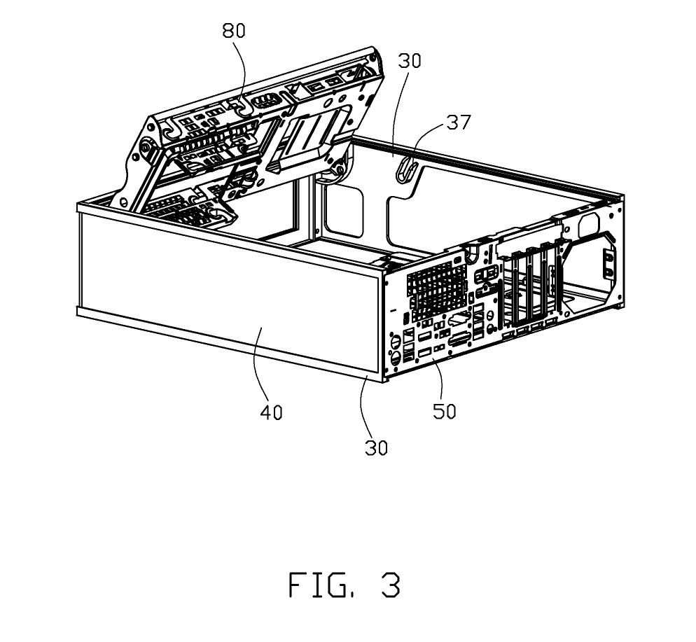

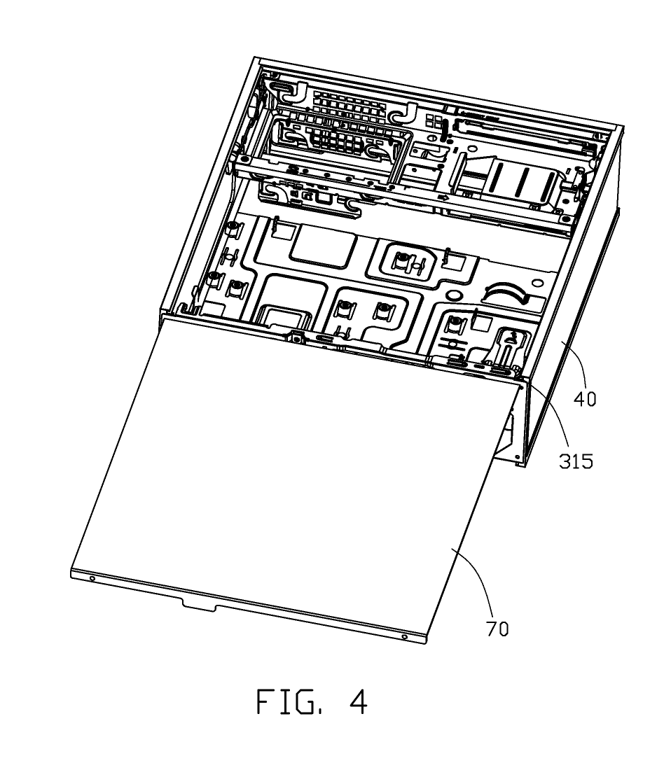

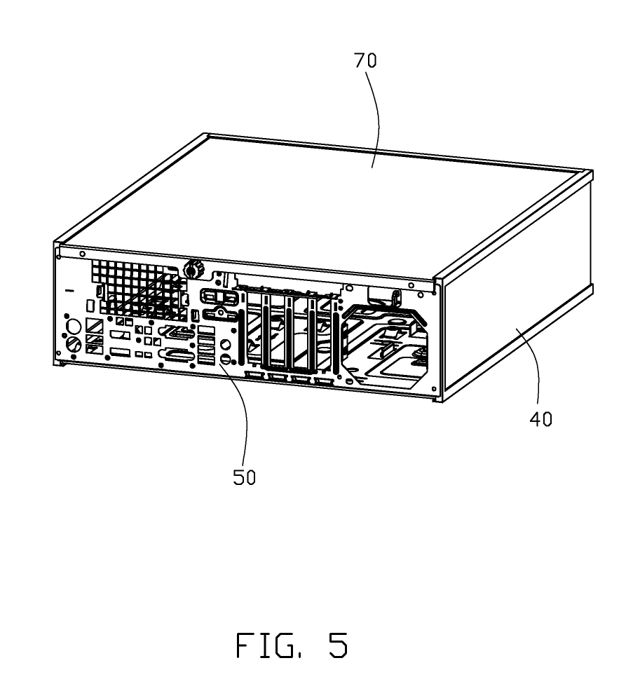

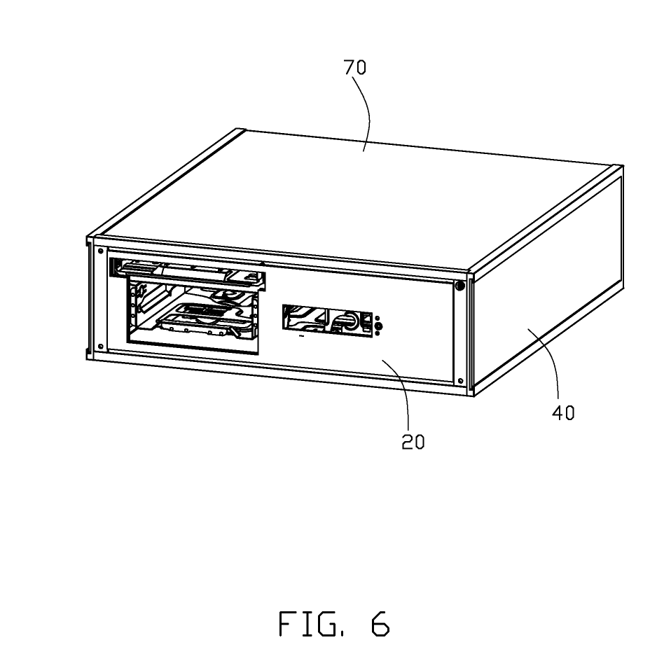

FIGS. 3-6 illustrate in assembly of the electronic device enclosure 100. A top edge and a bottom edge of the front panel 20 are slid into the two front panel sliding slots 13 in a direction that is substantially parallel to the front frame body to secure to the front frame body 11. The holes 21 are aligned with the openings 111, and a left edge and a right edge of the front panel 20 are inserted into the clipping portions 341. The securing holes 116 are aligned with the fixing holes 391, a plurality of mounting members (not shown), such as screws, is engaged in the securing holes 116 and the fixing holes 391 to secure the front frame 10 to the two side frame 30. A top edge and a bottom edge of the side panel 40 are slid into the side panel sliding slots 33 to secure the side panel 40 to the side frame 30.

The bottom panel 60 is secured to the bottom surface of the bottom portion 51 by means, such as screws, plaster. The opposite side edges of the bottom panel 60 are aligned with the two accommodating slots 315 to slid into the two accommodating slots 315, until a front edge of the bottom panel 60 inserts into the receiving slot 115 of the front frame 10. The through holes 522 are aligned with the fixing holes 391, a plurality of mounting members (not shown), such as screws, is engaged in the through holes 522 and the fixing holes 391 to secure the bottom frame 50 to the two side frames 30.

The bracket 80 is operated to allow the rotating post 81 of each side portion 81 to engage in the rotating hole 35 of each side frame 30, thereby the bracket 80 is rotatably coupled to the two side frames 30. The bracket 80 is rotated for allowing the sliding posts 812 to slide into the sliding slot 361 of each side frame 30, until the protruding post 813 is located in the supporting portion 37 to prevent the bracket 80 from moving.

Opposite side edges of the top panel 70 are slid into the accommodating slots 315, until a front edge of the top panel 70 is inserted into the accommodating slot 115. Thus, the electronic device enclosure 100 is assembled.

The embodiments shown and described above are only examples. Many details are often found in the art such as the other features of an electronic device enclosure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electronic device enclosure comprising:
a front frame comprising: a front frame body and a front flange extending from the front frame body to define a front panel sliding slot; and
a front panel made of non-metal material and is slidably received in the front panel sliding slot, thereby the front panel is coupled to the front frame.

2. The electronic device enclosure of claim 1, further comprising a top panel and a bottom panel; wherein a pair of limiting ribs extends from each of opposite edges of the front frame body to define a receiving slot, an edge of the top panel is engaged in the receiving slot of a top portion of the front frame body, and an edge of the bottom panel is engaged in the receiving slot of a bottom portion of the front frame body.

3. The electronic device enclosure of claim 1, further comprising a top panel, a bottom panel, a side frame and a side panel, wherein the side frame comprises a side frame body, a side flange extends from the side frame body to define a side panel sliding slot, and the side panel is made of nonmetal material and is slidable received in the side panel sliding slot, thereby the side panel is coupled to the side frame.

4. The electronic device enclosure of claim 3, wherein a pair of limiting pieces extends from each of opposite edges of the side frame body to define an accommodating slot, an edge of the top panel is engaged in the accommodating slot of a top portion of the side frame body, and an edge of the bottom panel is engaged in the accommodating slot of a bottom portion of the side frame body.

5. The electronic device enclosure of claim 4, wherein the side frame body defines a rotating hole, a bracket comprises a rotating shaft, and the rotating shaft is engaged in the rotating hole to rotatably secure the bracket to the side frame body.

6. The electronic device enclosure of claim 5, wherein the side frame body further comprises two arcuate blocking pieces, an arcuate sliding slot is defined between the two arcuate blocking piece, and the bracket further comprises a sliding post slidably received in the arcuate sliding slot.

7. The electronic device enclosure of claim 6, wherein a center of the arcuate sliding slot is coincided with the rotating hole.

8. The electronic device enclosure of claim 5, wherein the side frame body further comprises a supporting portion, and the bracket further comprises a protruding post engaged in the supporting portion for prevent the bracket from moving.

9. The electronic device enclosure of claim 1, further comprising a bottom frame and a bottom panel, wherein the bottom frame comprises a bottom portion and a rear portion, and the bottom panel is coupled to a bottom surface of the bottom frame.

10. The electronic device enclosure of claim 1, wherein the nonmetal material is paper, or wood, or bamboo, or plastic.

11. An electronic device enclosure comprising:
a front frame comprising a front frame body; a front flange located on the front frame body and comprising a coupling portion and a bending portion, the front frame body, the coupling portion and the bending portion cooperatively defining a front panel sliding slot; and
a front panel made of nonmetal material and is slidable received in the front panel sliding slot in a direction that is substantially parallel to the front frame body, thereby the front panel is coupled to the front frame.

12. The electronic device enclosure of claim 11, further comprising a top panel and a bottom panel; wherein a pair of limiting ribs extends from each of opposite edges of the front frame body to define a receiving slot, an edge of the top panel is engaged in the receiving slot of a top portion of the front frame body, and an edge of the bottom panel is engaged in the receiving slot of a bottom portion of the front frame body.

13. The electronic device enclosure of claim 11, further comprising a top panel, a bottom panel, a side frame and a side panel, wherein the side frame comprises a side frame body, a side flange extends from the side frame body to define a side panel sliding slot, and the side panel is made of nonmetal material and is slidably received in the side panel sliding slot, thereby the side panel is coupled to the side frame.

14. The electronic device enclosure of claim 13, wherein a pair of limiting pieces extends from each of opposite edges of the side frame body to define an accommodating slot, an edge of the top panel is engaged in the accommodating slot of a top portion of the side frame body, and an edge of the bottom panel is engaged in the accommodating slot of a bottom portion of the side frame body.

15. The electronic device enclosure of claim 14, wherein the side frame body defines a rotating hole, a bracket comprises a rotating shaft, and the rotating shaft is engaged in the rotating hole to rotatably secure the bracket to the side frame body.

16. The electronic device enclosure of claim 15, wherein the side frame body further comprises two arcuate blocking pieces, an arcuate sliding slot is defined between the two arcuate blocking piece, and the bracket further comprises a sliding post slidably received in the arcuate sliding slot.

17. The electronic device enclosure of claim 16, wherein a center of the arcuate sliding slot is coincided with the rotating hole.

18. The electronic device enclosure of claim 15, wherein the side frame body further comprises a supporting portion, and the bracket further comprises a protruding post engaged in the supporting portion for prevent the bracket from moving.

19. The electronic device enclosure of claim 11, further comprising a bottom frame and a bottom panel, wherein the bottom frame comprises a bottom portion and a rear portion, and the bottom panel is coupled to a bottom surface of the bottom frame.

20. The electronic device enclosure of claim 11, wherein the nonmetal material is paper, or wood, or bamboo, or plastic.
